(19) United States
(12) Patent Application Publication
(10) Pub. No.: US 2024/0260486 A1
(43) Pub. Date: Aug. 1, 2024

(54) SYSTEMS AND METHODS FOR QUANTUM COMPUTING USING FLUXONIUM QUBITS WITH KINETIC INDUCTORS

(71) Applicant: 1372934 B.C. LTD., Burnaby (CA)

(72) Inventors: Jed D. Whittaker, Vancouver (CA); Trevor M. Lanting, Vancouver (CA)

(21) Appl. No.: 18/290,587

(22) PCT Filed: Jul. 18, 2022
(86) PCT No.: PCT/US2022/037457

§ 371 Date: Jan. 19, 2024

Related U.S. Application Data
(60) Provisional application No. 63/223,686, filed on Jul. 20, 2021.

(51) Int. Cl. H10N 69/00; H01F 27/28; H10N 60/01; H10N 60/12

(52) U.S. Cl. CPC H10N 69/00; H01F 27/2804; H10N 60/0912; H10N 60/12

(57) ABSTRACT

A superconducting device may have a body loop comprising a body loop comprising a Josephson junction structure and a kinetic inductor. The superconducting device can be a qubit in a quantum processor for performing gate-model quantum computation. The superconducting device may be fabricated with a single wiring layer embedded in a single-crystalline substrate trench. The superconducting device may be fabricated with a wiring layer and an insulating layer in a single-crystalline substrate trench. The superconducting device may be fabricated with multiple wiring layers embedded in a single-crystalline substrate trench. The device may be fabricated by defining trenches in the single-crystalline substrate, with the trenches having a depth matching the desired numbers of wiring layers and insulating layers.

### FIELD

This disclosure generally relates to Fluxonium qubits comprising kinetic inductors and methods of fabrications thereof.

### BACKGROUND

### Noise in a Quantum Processor

Low-noise is a desirable characteristic of quantum devices. Noise can compromise or degrade the functionality of the individual devices, such as superconducting qubits, and of the superconducting processor as a whole. Noise can negatively affect qubit coherence and reduce the efficacy of qubit tunneling. Since noise is a serious concern to the operation of quantum processors, it is desirable to take measures to reduce noise wherever possible so that a transition from coherent to incoherent tunneling is not induced by the environment.

Impurities may be deposited on the metal surface and/or may arise from an interaction with the etch/photoresist chemistry and the metal. Noise can be caused by impurities on the upper surface of the quantum processor. In some cases, superconducting devices that are susceptible to noise are fabricated in the top wiring layers of a superconducting integrated circuit and are thus sensitive to post-fabrication handling. There is a risk of introducing impurities that cause noise during post-fabrication handling. One approach to reducing noise is using a barrier passivation layer, for example, an insulating layer, to overlie the topmost wiring layer. The use of a barrier passivation layer to minimize noise from impurities on the upper surface of a quantum processor is described in U.S. Pat. No. 10,454,015.

Noise can also result from an external environment or surrounding circuitry in a superconducting processor. In a quantum annealing processor, flux noise on qubits interferes with properly annealing the quantum processor because of the steep transition between qubit states as the flux bias is swept. Flux noise can be a result of current flowing through wiring of other devices included in the superconducting processor and can have a particularly negative effect on qubits at their respective degeneracy points. For example, flux noise can introduce errors in calculations carried out by the superconducting processor due to inaccuracies in setting flux bias and coupling strength values. Reducing or even eliminating such inaccuracies may be particularly advantageous in using an integrated circuit as part of a quantum processor. Much of the static control error can be designed out of the processor with careful layout and high-precision flux sources, as well as by adding circuitry, such as an on-chip shield, to tune away any non-ideal flux qubit behavior. However, in many cases, limitations in integrated circuit fabrication capabilities can make it difficult to address noise by changing processor layout and adding circuitry. There is therefore a general desire for articles and methods for fabricating integrated circuits that have reduced flux noise (and thus improved coherence) without having to compromise the quantum processor layout by adding additional layers or circuitry.

### Josephson Junctions

A Josephson junction is a common element in superconducting integrated circuits. Physically, a Josephson junction is a small interruption in an otherwise continuous superconducting current path, typically realized by a thin insulating barrier sandwiched in between two superconducting electrodes. In superconducting integrated circuits, Josephson junctions are typically fabricated as a stack comprising a superconducting base electrode overlaid with a thin insulating layer, which is then overlaid with a superconducting counter electrode. Thus, a Josephson junction is usually formed as a three-layer, or “trilayer,” structure. A trilayer may be deposited completely over an entire wafer (i.e., in the same way that metal wiring and dielectric layers are deposited) and then patterned to define individual Josephson junctions.

### Kinetic Inductance

Current flowing through a metal material in principle stores energy both in the magnetic field of that metal and in the kinetic energy of the charge carriers (e.g., the electrons or Cooper pairs). In non-superconducting metals, the charge carriers collide frequently with the lattice and lose their kinetic energy as Joule heating. This is also referred to as scattering, and quickly releases energy. However, in superconducting materials, scattering is substantially reduced, as the charge carriers are Cooper pairs which are protected against dissipation through scattering. This allows for superconducting materials to store energy in the form of kinetic inductance. This phenomenon allows kinetic inductance to efficiently store energy within the superconducting metal. Kinetic inductance is at least in part determined by the inertial mass of the charge carriers of a given material and increases as carrier density decreases. As the carrier density decreases, a smaller number of carriers must have a proportionally greater velocity in order to produce the same current. Materials that have high kinetic inductance for a given area (as defined below) are referred to as “kinetic inductance materials”, or “high kinetic inductance materials”.

Kinetic inductance materials are those that have a high normal-state resistivity and/or a small superconducting energy gap, resulting in a larger kinetic inductance per unit of area. In general, total inductance L of a superconducting material is given by L=L_{K}+L_{G}, where L_{G} is the geometric inductance and L_{K} is the kinetic inductance. The kinetic inductance of a superconducting film in near-zero temperatures is proportional to the effective penetration depth λ_{eff}. In particular, for a film with a given thickness t, the kinetic inductance of the film is proportional to the ratio of the length of the film L to the width of the film W, where length is in the direction of the current and width is orthogonal to length (note that both width and length are orthogonal to the dimension in which thickness is measured). That is, L_{K}˜λ_{eff}L/W for a superconducting film with a given thickness. The kinetic inductance fraction of a material is characterized as

$$α = \frac{{L}_{k}}{{L}_{g} + {L}_{k}} .$$

A material considered to have high kinetic inductance would typically have a in the range of 0.1<α≤1. Materials with less than 10% of the energy stored as kinetic inductance would be considered traditional magnetic storage inductors with a small correction.

In some implementations it may be beneficial to attempt to maximize kinetic inductance in minimal volume. This may include attempting to minimize the width of the film, selecting a suitable material with a high effective penetration depth λ_{eff}, and selecting a length for the film which achieves the desired kinetic inductance. It may also be beneficial to attempt to minimize the thickness t of the material, subject to fabrication constraints, as for t<3λ_{eff(bulk)} (where λ_{eff(bulk)} is the effective penetration depth of the material in bulk, not thin-film), λ_{eff} increases at least approximately proportionately to 1/t². In some implementations, t<n·λ_{eff(bulk)}, where n is some value substantially less than 1 (e.g., 0.5, 0.1, 0.05, 0.01, etc.).

### Integrated Circuit Fabrication

Traditionally, the fabrication of superconducting integrated circuits has not been performed at state-of-the-art semiconductor fabrication facilities. This may be due to the fact that some of the materials used in superconducting integrated circuits can contaminate the semiconductor facilities.

Superconductor fabrication has typically been performed in research environments where standard industry practices could be optimized for superconducting circuit production. Superconducting integrated circuits are often fabricated with tools that are traditionally used to fabricate semiconductor chips or integrated circuits. Owing to issues peculiar to superconducting circuits, not all semiconductor processes and techniques are necessarily transferrable to superconductor chip manufacture. Transforming semiconductor processes and techniques for use in superconductor chip and circuit fabrication often requires changes and fine adjustments. Such changes and adjustments typically are not obvious and may require a great deal of experimentation. The semiconductor industry faces problems and issues not necessarily related to the superconducting industry. Likewise, problems and issues that concern the superconducting industry are often of little or no concern in standard semiconductor fabrication.

Any impurities within superconducting chips may result in noise which can compromise or degrade the functionality of the individual devices, such as superconducting qubits, and of the superconducting chip as a whole. Since noise is a serious concern to the operation of quantum computers, measures should be taken to reduce dielectric noise wherever possible.

### Etching

Etching removes layers of, for example, substrates, dielectric layers, oxide layers, electrically insulating layers and/or metal layers according to desired patterns delineated by photoresists or other masking techniques. Two exemplary etching techniques are wet chemical etching and dry chemical etching.

Wet chemical etching or “wet etching” is typically accomplished by submerging a wafer in a corrosive bath such as an acid bath. In general, etching solutions are housed in polypropylene, temperature-controlled baths.

Dry chemical etching or “dry etching” is commonly employed due to its ability to better control the etching process and reduce contamination levels. Dry etching effectively etches desired layers through the use of gases, either by chemical reaction such as using a chemically reactive gas or through physical bombardment, such as plasma etching, using, for example, argon atoms.

### Planarization

The use of chemical-mechanical planarization (CMP) allows for a near flat surface to be produced. CMP is a standard process in the semiconductor industry. The CMP process uses an abrasive and corrosive chemical slurry in conjunction with a polishing pad and retaining ring, typically of a greater width than the wafer. The pad and wafer are pressed together by a dynamic polishing head and held in place by a plastic retaining ring. The dynamic polishing head is rotated with different axes of rotation (i.e., not concentric). This removes material and tends to even out any irregular topography, making the wafer flat or planar. The process of material removal is not simply that of abrasive scraping, like sandpaper on wood. The chemicals in the slurry also react with and/or weaken the material to be removed such that certain materials can be preferentially removed while leaving others relatively intact. The abrasive accelerates this weakening process and the polishing pad helps to wipe the reacted materials from the surface. Advanced slurries can be used to preferentially remove areas of the wafer that are relatively high or protrude in relation to areas of the wafer that are relatively low in order to planarize the topography of the wafer.

### Quantum Devices

Quantum devices are structures in which quantum mechanical effects are observable. Quantum devices include circuits in which current transport is dominated by quantum mechanical effects. Such devices include spintronics, and superconducting circuits. Both spin and superconductivity are quantum mechanical phenomena. Quantum devices can be used for measurement instruments, in computing machinery, and the like.

### Quantum Computation

A quantum computer is a system that makes direct use of at least one quantum-mechanical phenomenon, such as, superposition, tunneling, and entanglement, to perform operations on data. The elements of a quantum computer are qubits. Quantum computers can provide speedup for certain classes of computational problems such as computational problems simulating quantum physics.

### Superconducting Qubits

Superconducting qubits are solid state qubits based on circuits of superconducting materials. Operation of superconducting qubits is based on the underlying principles of magnetic flux quantization, and Josephson tunneling. Superconducting effects can be present in different configurations, and can give rise to different types of superconducting qubits including flux, phase, charge, and hybrid qubits. The different configurations can vary in the topology of the loops, the placement of the Josephson junctions, and the physical parameters of elements of the superconducting circuits, such as inductance, capacitance, and Josephson junction critical current.

### Approaches to Quantum Computation

There are several general approaches to the design and operation of quantum computers. One such approach is the “circuit” or “gate” model of quantum computation. In this approach, qubits are acted upon by sequences of logical gates that are the compiled representation of an algorithm. Much research has been focused on developing qubits with sufficient coherence to form the basic elements of circuit model quantum computers.

Another approach to quantum computation involves using the natural physical evolution of a system of coupled quantum devices as a computational system. This approach may not make use of quantum gates and circuits. Instead, the computational system may start from a known initial Hamiltonian with an easily accessible ground state and be controllably guided to a final Hamiltonian whose ground state represents the answer to a problem. This approach does not typically require long qubit coherence times. Examples of this type of approach include adiabatic quantum computation and quantum annealing.

### BRIEF SUMMARY

In at least one aspect, a superconducting device includes: a body loop comprising: a Josephson junction structure comprising at least one inductor in series with at least one Josephson junction; and a kinetic inductor, the kinetic inductor comprising a segment of kinetic inductance material. The body loop has a body loop material that can comprise at least one of Al and Nb.

In at least one aspect, a processor includes a plurality of superconducting devices, each superconducting device comprising: a body loop comprising: a Josephson junction structure comprising at least one inductor in series with at least one Josephson junction; and a kinetic inductor, the kinetic inductor comprising a segment of kinetic inductance material. The body loop has a body loop material that can comprise at least one of Al and Nb.

In at least one aspect a method of fabrication of a superconducting device includes, providing a high-resistivity layer; defining trenches in the high-resistivity layer; depositing a first superconducting wiring layer to overlie at least a portion of the high-resistivity layer and within the trenches, wherein the first superconducting wiring layer comprises material that is superconducting in a range of critical temperatures; and removing a portion of the first superconducting wiring layer from the high-resistivity layer to define the first superconducting wiring layer within the trenches.

In at least one aspect a method of fabrication of a superconducting device includes, providing a high-resistivity layer; defining trenches in the high-resistivity layer; depositing a first superconducting wiring layer to overlie at least a portion of the high-resistivity layer and within the trenches, wherein the first superconducting wiring layer comprises material that is superconducting in a range of critical temperatures; removing a first portion of the first superconducting wiring layer from the high-resistivity layer to define the first superconducting wiring layer within the trenches; defining a photoresist over a first region of the first superconducting wiring layer within the trenches; removing a second portion of the first superconducting wiring layer to define studs for vias; depositing a dielectric layer to overlie the first superconducting wiring layer; and removing a first portion of the dielectric layer to define the dielectric layer within the trenches.

In at least one aspect a method of fabrication of a superconducting device includes, providing a high-resistivity layer; defining trenches in the high-resistivity layer; until i=N and j=N, where N>1, repeating: depositing an i^{th} superconducting wiring layer to overlie at least a portion of the high-resistivity layer and within the trenches, wherein the i^{th} superconducting wiring layer comprises material that is superconducting in a range of critical temperatures; removing a respective first portion of the i^{th} superconducting wiring layer from the high-resistivity layer to define the i^{th} superconducting wiring layer within the trenches; defining a photoresist over a respective first region of the i^{th} superconducting wiring layer within the trenches; removing a respective second portion of the i^{th} superconducting wiring layer to define studs for vias; depositing a j^{th} dielectric layer to overlie the i^{th} superconducting wiring layer; removing a respective first portion of the j^{th} dielectric layer to define the j^{th} dielectric layer in the trenches; defining a photoresist over a respective first region of the j^{th} dielectric layer within the trenches; and removing a respective second portion of the j^{th} dielectric layer.

### BRIEF DESCRIPTION OF THE SEVERAL VIEWS OF THE DRAWING(S)

In the drawings, identical reference numbers identify similar elements or acts. The sizes and relative positions of elements in the drawings are not necessarily drawn to scale. For example, the shapes of various elements and angles are not necessarily drawn to scale, and some of these elements may be arbitrarily enlarged and positioned to improve drawing legibility. Further, the particular shapes of the elements as drawn, are not necessarily intended to convey any information regarding the actual shape of the particular elements, and may have been solely selected for ease of recognition in the drawings.

FIG. 1 illustrates a hybrid computing system including a classical computer coupled to a quantum computer, the quantum computer which can employ one or more of the structures described herein.

FIG. 2 is a schematic diagram of an example superconducting qubit including a kinetic inductor.

FIGS. 3A through 3E are respective cross-sectional views of a portion of an example superconducting qubit including a kinetic inductor at sequential phases of a fabrication process with a single wiring layer in Silicon trenches, according to at least one illustrated implementation.

FIG. 4 is a flow diagram of an example fabrication method to produce the structures illustrated in FIGS. 3A through 3E.

FIGS. 5A through 5H are respective cross-sectional views of a portion of an example superconducting qubit including a kinetic inductor at sequential phases of a fabrication process with a wiring layer and an insulating layer in a trench, according to at least one other illustrated implementation.

FIG. 6 is a flow diagram of an example fabrication method to produce the structures illustrated in FIGS. 5A through 5H.

FIGS. 7A through 7T are respective cross-sectional views of a portion of an example superconducting qubit including a kinetic inductor at sequential phases of a fabrication process, according to at least one illustrated implementation.

FIG. 8 is a flow diagram of an example fabrication method to produce the structures illustrated in FIGS. 7A through 7T.

### DETAILED DESCRIPTION

In the following description, certain specific details are set forth in order to provide a thorough understanding of various disclosed implementations. However, one skilled in the relevant art will recognize that implementations may be practiced without one or more of these specific details, or with other methods, components, materials, etc. In other instances, well-known structures associated with computer systems, server computers, and/or communications networks have not been shown or described in detail to avoid unnecessarily obscuring descriptions of the implementations.

Unless the context requires otherwise, throughout the specification and claims that follow, the word “comprising” is synonymous with “including,” and is inclusive or open-ended (i.e., does not exclude additional, unrecited elements or method acts).

Reference throughout this specification to “one implementation” or “an implementation” means that a particular feature, structure or characteristic described in connection with the implementation is included in at least one implementation. Thus, the appearances of the phrases “in one implementation” or “in an implementation” in various places throughout this specification are not necessarily all referring to the same implementation. Furthermore, the particular features, structures, or characteristics may be combined in any suitable manner in one or more implementations.

As used in this specification and the appended claims, the singular forms “a,” “an,” and “the” include plural referents unless the context clearly dictates otherwise. It should also be noted that the term “or” is generally employed in its sense including “and/or” unless the context clearly dictates otherwise.

The headings and Abstract of the Disclosure provided herein are for convenience only and do not interpret the scope or meaning of the implementations.

### Hybrid Quantum Computing System

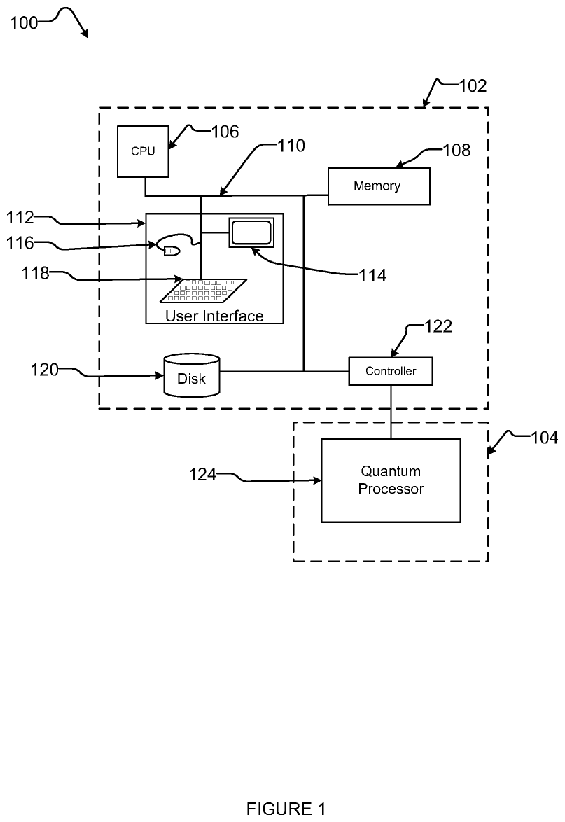

FIG. 1 illustrates a hybrid computing system 100 including a classical computer 102 coupled to a quantum computer 104. The example classical computer 102 includes a digital processor (CPU) 106 that may be used to perform classical digital processing tasks, and hence is denominated herein and in the claims as a classical processor.

Classical computer 102 may include at least one digital processor (such as central processor unit 106 with one or more cores), at least one system memory 108, and at least one system bus 110 that couples various system components, including system memory 108 to central processor unit 106. The digital processor may be any logic processing unit, such as one or more central processing units (“CPUs”), graphics processing units (“GPUs”), digital signal processors (“DSPs”), application-specific integrated circuits (“ASICs”), programmable gate arrays (“FPGAs”), programmable logic controllers (PLCs), etc.

Classical computer 102 may include a user input/output subsystem 112. In some implementations, the user input/output subsystem includes one or more user input/output components such as a display 114, mouse 116, and/or keyboard 118.

System bus 110 can employ any known bus structures or architectures, including a memory bus with a memory controller, a peripheral bus, and a local bus. System memory 108 may include non-volatile memory, such as read-only memory (“ROM”), static random-access memory (“SRAM”), Flash NANO; and volatile memory such as random access memory (“RAM”) (not shown).

Classical computer 102 may also include other non-transitory computer or processor-readable storage media or non-volatile memory 120. Non-volatile memory 120 may take a variety of forms, including: a hard disk drive for reading from and writing to a hard disk, an optical disk drive for reading from and writing to removable optical disks, and/or a magnetic disk drive for reading from and writing to magnetic disks. The optical disk can be a CD-ROM or DVD, while the magnetic disk can be a magnetic floppy disk or diskette. Non-volatile memory 120 may communicate with the digital processor via system bus 110 and may include appropriate interfaces or controllers 122 coupled to system bus 110. Non-volatile memory 120 may serve as long-term storage for processor- or computer-readable instructions, data structures, or other data (sometimes called program modules) for classical computer 102.

Although classical computer 102 has been described as employing hard disks, optical disks and/or magnetic disks, those skilled in the relevant art will appreciate that other types of non-volatile computer-readable media may be employed, such magnetic cassettes, flash memory cards, Flash, ROMs, smart cards, etc. Those skilled in the relevant art will appreciate that some computer architectures employ volatile memory and non-volatile memory. For example, data in volatile memory can be cached to non-volatile memory, or a solid-state disk that employs integrated circuits to provide non-volatile memory.

Various processor- or computer-readable instructions, data structures, or other data can be stored in system memory 108. For example, system memory 108 may store instruction for communicating with remote clients and scheduling use of resources including resources on the classical computer 102 and quantum computer 104.

In some implementations system memory 108 may store processor- or computer-readable calculation instructions to perform pre-processing, co-processing, and post-processing to quantum computer 104. System memory 108 may store at set of quantum computer interface instructions to interact with quantum computer 104.

Quantum computer 104 may include one or more quantum processors such as quantum processor 124. Quantum computer 104 can be provided in an isolated environment, for example, in an isolated environment that shields the internal elements of the quantum computer from heat, magnetic field, and other external noise (not shown). Quantum processor 124 include programmable elements such as qubits, couplers and other devices. In some implementations, a quantum processor, such as quantum processor 124, may be designed to perform quantum annealing and/or adiabatic quantum computation. Example of quantum processor are described in U.S. Pat. No. 7,533,068. In accordance with the present disclosure, quantum processor 124 may be designed to perform gate-model quantum computation. The quantum computer 104, and quantum processor 124, can advantageously employ one or more of the structures described herein, for example one or more fluxonium qubits and/or a qubit or coupler comprising a conductive loop, a Josephson junction structure and a kinetic inductor. In the present application and the appended claims, the term ‘kinetic inductor’ is used to denote an inductor stores the majority of its energy in the kinetic energy of its Cooper pairs, and a much smaller fraction of its energy as classical magnetic energy.

### Fluxonium Qubits

Throughout the present specification, the phrase “noise-susceptible superconducting device” is used to describe a superconducting device for which noise may adversely affect the performance of a quantum processor. Poor performance of a noise-susceptible device may result in the quantum processor producing inaccurate or suboptimal solutions to a problem. For example, a qubit may be considered a noise-susceptible device or device that is susceptible to noise. Note that the phrase “noise-susceptible” or “susceptible to noise” does not necessarily suggest that the device itself is physically more or less sensitive to noise compared to other devices that are not described as noise-susceptible. Sensitivities to processor performance is higher in noise-susceptible devices relative to devices that are described as less susceptible to noise.

Noise in a quantum processor may cause qubits to decohere which reduces the efficacy of tunneling. As a result, processor performance may be diminished, and solutions generated from the processor may be suboptimal. Existing approaches for improving coherence include adding circuitry to shield qubits or making significant modifications to processor layouts which, in some cases, may be impractical. The present disclosure describes an advantageous approach in which coherence may be improved in a quantum processor.

Performance of a superconducting processor may be easily affected by the performance of certain superconducting devices that are susceptible to noise, for example, qubits and couplers. Since processor performance is particularly sensitive to proper or improper operation of these devices, it is desirable to reduce noise in these devices as much as possible. For a superconducting processor, one of the dominant sources of environmental noise is flux noise. Flux noise may cause decoherence which induces a transition from coherent to incoherent tunneling before the transition is induced by intrinsic phase transitions. Device decoherence during computation may limit the speed and/or accuracy with which the processor evolves and produces solutions.

A superconducting quantum processor may include other types of qubits besides superconducting flux qubits. For example, a superconducting quantum processor may include superconducting charge qubits, transmon qubits, and the like. A superconducting qubit may include a shunt capacitor. Examples of qubits that use a shunt capacitor include a three-junction flux qubit, a zero-pi qubit, a fluxonium qubit, a bifluxon qubit, and a transmon.

A Fluxonium is a qubit which consists of a Josephson junction shunted by a superinductor, typically formed by an array of Josephson junctions. In the present application and the appended claims, the term ‘superinductor’ or ‘superinductance’ is used to define inductance that can be used to construct electrical circuits in which quantum electrodynamics of charges and fluxes is governed by an effective fine structure constant over a unity. The number of Josephson junctions may vary in different implementations. The superinductor shunts charge noise.

Fluxonium Qubits with Kinetic Inductance

Fluxonium qubits may be used for gate-model quantum computing (GMQC). In particular, Fluxonium qubits may be employed in a multi-layer fabrication stack that allows multiplexed control circuitry to be built around Fluxonium qubits.

As mentioned before, it is advantageous for a fabrication stack to possess high-coherence. It is particularly advantageous to increase coherence around the Josephson junction layer of the fabrication stack, since fluxonium qubits may be built using large array of Josephson junctions in series to make a superinductance. Therefore, there exists a need to reduce charge noise in the junctions layer.

A possible method for decreasing charge noise in junction layers is to surround the qubit body with a low-charge noise material like Silicon Nitride (SiN). However, SiN can also have high-flux noise, which can lower T₂ lifetime. It is desirable for both T₁ and T₂ to be relatively long times in GMCQ applications. This approach may increase the qubit T₁ lifetime by 5-10 times; however, to further increase coherence, the dielectric around the junctions should also be a lower-noise material. Replacing existing dielectrics with more exotic, low-noise dielectrics tends to be difficult, as the junction fabrication process is quite sensitive to perturbations. Each time a new dielectric is introduced in a fabrication stack the junction process has to be redeveloped, rendering the approach infeasible in the long term.

Another approach to increase qubits coherence is to build the fabrication layer with the junctions overlaying a low-charge-noise and low-flux-noise Silicon wafer dielectric. As mentioned above, it is desirable for GMQC to use both low-charge- and low-flux-noise materials. However, this limits the dielectric deposition temperature and stud via technology that are available for the rest of the processor fabrication.

A more advantageous approach is to build the superinductance of a fluxonium qubit, that traditionally comprises an array of Josephson junctions, with a kinetic inductor.

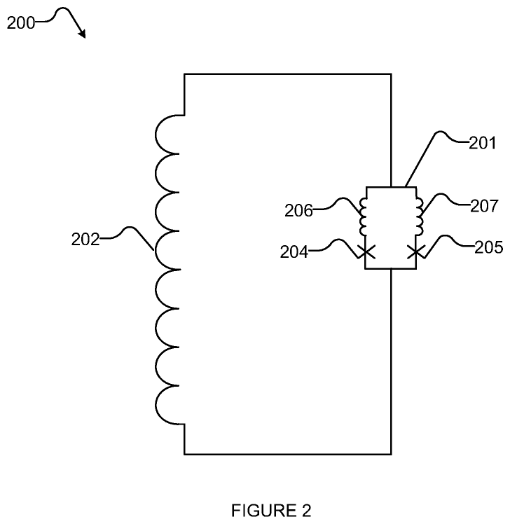

FIG. 2 is a schematic diagram of an example superconducting qubit 200 that replaces the array of Josephson junctions of a fluxonium qubit with a kinetic inductor. Qubit 200 comprises a Josephson junction structure 201 and a kinetic inductor 202. In the present example implementation, Josephson junction structure 201 comprises two Josephson junctions 204 and 205 to form a compound Josephson junction (CJJ). Josephson junction 204 is in series with an inductor 206, and Josephson junction 205 is in series with an inductor 207. A person skilled in the art will understand that Josephson junction structure 201 may include only one Josephson junction or include compound-compound Josephson junctions (CCJJ) and in certain implementations inductors 206 and 207 may not be present.

Kinetic inductor 202 may comprise Niobium Nitride (NbN), Niobium Titanium Nitride (NbTiN) or Titanium nitride (TiN), Aluminum Nitride (AlN) or granular Aluminum. Kinetic inductor 202 may be built at or relatively toward a bottom of a fabrication stack, overlaying a low-noise Silicon dielectric layer, while maintaining Josephson junction structure 201 at or relatively toward a top of the fabrication stack, to improve coherence of superconducting qubit 200.

In one example implementation, kinetic inductor 202 may have an inductance of 5 nH. Table 1 shows the length of an example 0.25 μm-wide wire needed to achieve a desired inductance.

TABLE 1

| | Length at | Length at | Length at |
|---|---|---|---|
| L_{KI} (nH) | 5 pH/sq (um) | 20 pH/sq (um) | 50 pH/sq (um) |
| 1 | 50 | 12.5 | 5 |
| 5 | 250 | 62.5 | 25 |
| 10 | 500 | 125 | 50 |
| 50 | 2,500 | 625 | 250 |
| 100 | 5,000 | 1,250 | 500 |

It is to be noted that at 5 pH/sq the wire lengths are relatively long, effectively turning fluxonium qubits into flux qubits, thus making them susceptible to noise. One approach to mitigate noise is to increase the inductance of kinetic inductor 202 by fabricating thinner layers of kinetic inductance material, for example 5 nm thick NbN films. Another approach to increase the inductance per square of kinetic inductor 202 by changing the chemistry of the kinetic inductance layer, e.g., by increasing the flow rate of Nitrogen during deposition.

### Fabrication of Lower Noise Qubits

As mentioned before, superconducting qubits of all types are plagued by both charge and flux noise, and the main noise sources are often the materials the qubits are made from. For this reason, most of the superconducting qubit community has preferred single-layer fabrication stacks, usually just one superconducting metal layer on top of either a silicon or sapphire wafer. While the single-layer fab stack can yield high-coherence qubits, they are of limited utility for large quantum processor with a large number of qubits because of wire routing issues. Multi-layer fab stacks offer ready solutions to those wire routing problems, so a desirable move toward scalable quantum computing is a multi-layer fabrication stack that also has high coherence.

Devices made with shielding layers around at least one of the wiring layers in the fabrication stacks have shown improved coherence relative to devices built without shielding layers. This suggest the shielding layers may provide a positive effect in i) keeping the electric and magnetic fields generated by currents in the qubit wires from sampling defects in the volume above the wiring layer with the added shielding, and/or ii) pushing the electric and magnetic fields into layers below the wiring layers, e.g., thermal oxide layers and c-silicon layers.

The evidence suggests that both the flux noise and the charge noise are lowered by this geometry change. Current models of dielectric loss from two-level systems (TLSs) describe loss channels in a dielectric or at an interface by talking about a defect density (C. Mller, J. H. Cole, J. Lisenfeld Towards understanding two-level-systems in amorphous solids: insights from quantum circuits, Reports on Progress in Physics 82 124501 (2019)). The larger the area or volume filled by the lossy dielectric, the larger the number of TLS defects available to leech energy from the qubit. Similar models describe the spin defects that cause flux noise. Therefore, reducing the volume and surface area of noisy dielectrics and interfaces may increase the coherence of qubits for a given defect density. High-resistivity c-silicon is known to have very low paramagnetic and charge defect densities. Typically, superconducting gate-model quantum computing groups use sapphire wafers because the charge noise tends to be about an order of magnitude lower (tan δ=10⁻⁶ vs. tan δ=10⁻⁵). However, those groups also tend to use qubits that are fairly insensitive to flux noise.

Flux qubits are quite sensitive to paramagnetic defects, so the high paramagnetic spin defect density of sapphire (σ˜10¹⁵/cm³) may makes sapphire an unacceptable substrate. Embedding qubits and couplers in c-silicon would therefore be very advantageous for the reasons stated above.

A very good deposited dielectric measured to date in superconducting qubits is hydrogenated amorphous silicon (a-Si:H), which in the literature has yielded qubit lifetimes of up to T₁˜500 ns (Lucero, E. A. Computing prime factors using a Josephson phase-qubit architecture: 15=35 Thesis pages 40 and 185-186 (2012)). While this could be pushed into the several-microsecond regime with rigorous materials science work, it still falls short of what is desired for use in a general-purpose, high-coherence quantum computing fabrication stack. A dielectric like a-Si is advantageous to use overlaying qubits; however, it is also desirable to minimize the volume of deposited dielectric and maximize the volume of single-crystalline dielectric to which the qubits are exposed.

The system and methods of the present disclosure describe how to embed most of the qubit body in a single-crystalline substrate, for example a c-silicon, Sapphire, or Germanium substrate, using a Damascene-like process. The qubit could be a fluxonium qubit comprising a large kinetic inductor, for example qubit 200 of FIG. 2.

### A Single Wiring Layer Embedded in a Single-Crystalline Substrate Trench

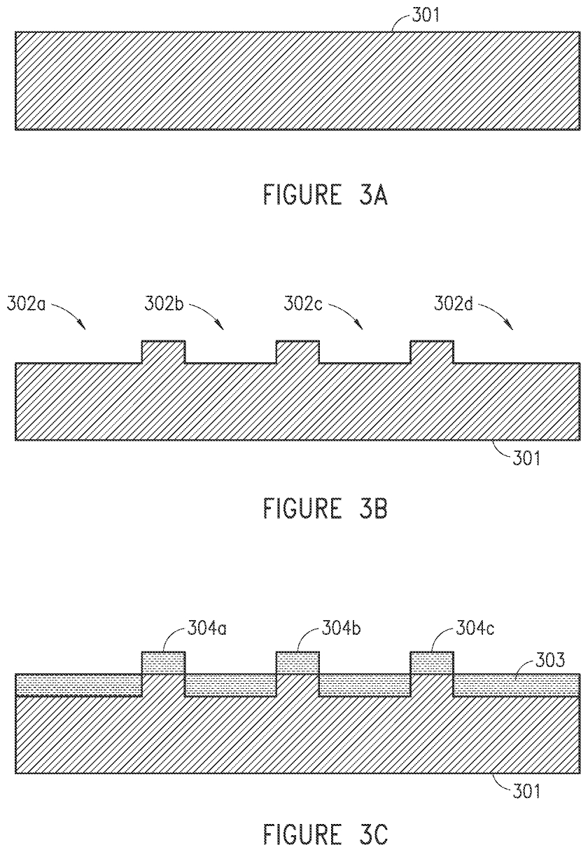

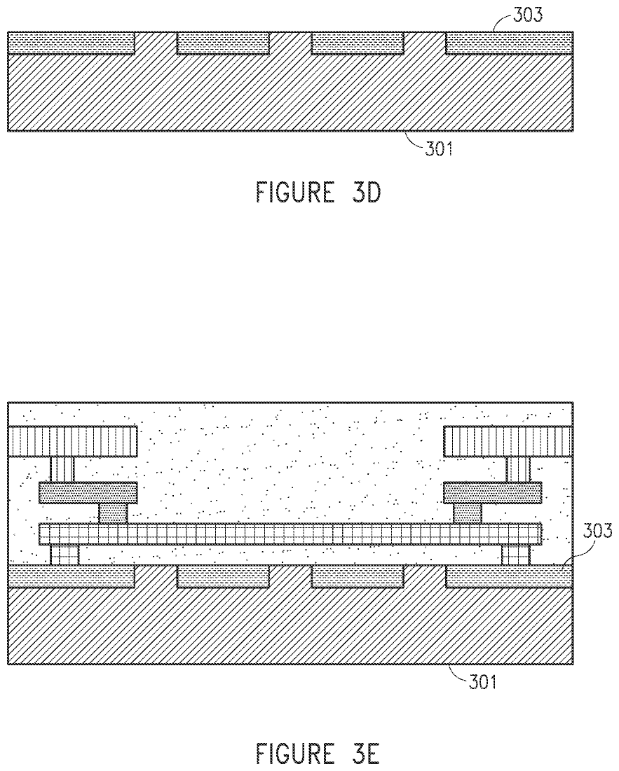

FIGS. 3A through 3E are respective cross-sectional views of a portion of an example superconducting qubit at sequential phases of a fabrication process, with a single wiring layer embedded in a single-crystalline substrate trench. The superconducting qubit may be a fluxonium qubit with a kinetic inductor, for example superconducting qubit 200 of FIG. 2. In one example implementation, the single-crystalline substrate is a c-silicon wafer with high-resistivity, usually 3,000-5,000 Ω·cm.

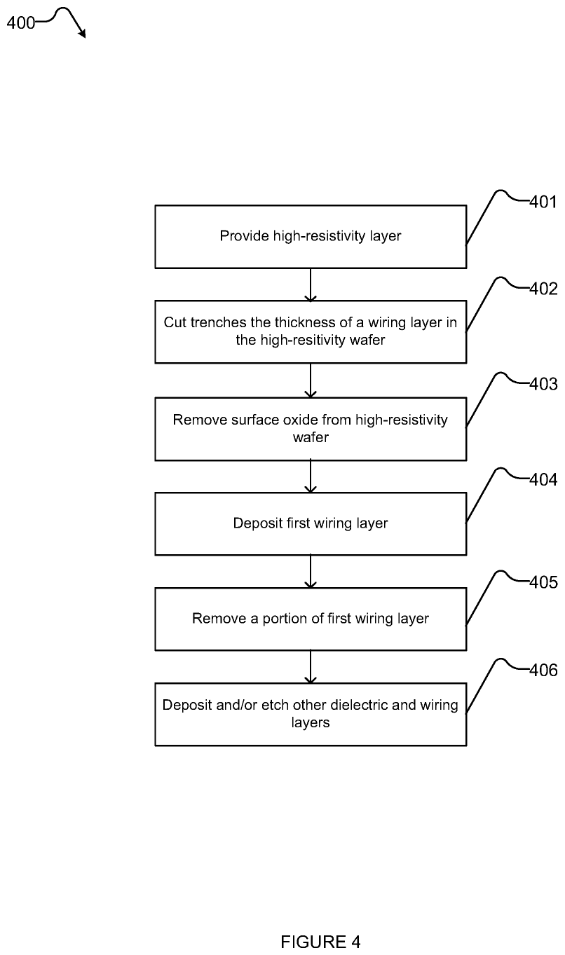

FIG. 4 is a flow diagram of an example fabrication method 400 to produce the structures illustrated in FIGS. 3A through 3E. FIG. 4 will be described with reference to FIGS. 3A though 3E. Method 400 comprises acts 401 to 406; however, a person skilled in the art will understand that the number of acts is exemplary and, in some implementations, certain acts may be omitted, further acts may be added, and/or the order of the acts may be changed. Method 400 may be performed by fabrication equipment.

At 401, the fabrication equipment provides a high-resistivity substrate or layer 301. High-resistivity substrate or layer 301 may be a single-crystalline substrate, for example a c-silicon wafer.

At 402, the fabrication equipment cuts (e.g., etches) trenches 302a through 302d (collectively, 302) in high-resistivity wafer 301, as shown in FIG. 3B. In FIG. 3B, four trenches are shown; however, a person skilled in the art would understand that the number and the location of the trenches shown in FIGS. 3B through 3E is for example purposes only and in different implementations a larger or smaller number of trenches may be cut at 402. The thickness or depth of trenches 302 is equivalent to the thickness or height of a wiring layer to be deposited in trenches 302. In one implementation, trenches 302 are 300 nm thick or deep for Al wiring layers, while in other implementations trenches are 50 nm thick or deep for NbN wiring layers. The location of trenches 302 corresponds to the location on where a wiring layer will be defined in the fabrication stack.

At 403 the fabrication equipment removes surface oxide from high-resistivity wafer 301. In some implementations, the fabrication equipment removes surface oxide using a Hydrofluoric acid (HF) dip or an RCS clean.

At 404, the fabrication equipment deposits a first wiring layer 303 to at least partially overlie high-resistivity layer 301, so that first wiring layer 303 is defined in trenches 302 and completely fills trenches 302 and possibly extends upwardly from portions of the high-resistivity layer 301 that surround the trenches 302, overlying the upper surface of high-resistivity layer 301. First wiring layer 303 may be a Niobium (Nb), Aluminum (Al) or Tantalum (Ta) layer. In some implementations, first wiring layer 303 may comprise the kinetic inductor of a superconducting qubit, e.g., kinetic inductor 202 of qubit 200.

At 405, the fabrication equipment removes portions 304a through 304c (collectively, 304) of first wiring layer 303. Portions 304 of first wiring layer 303 extend outwardly with respect to those portions deposited in trenches 302. A person skilled in the art will understand that the number of portions 304 to be removed varies in different implementation. In some implementations, the fabrication equipment polishes off portions 304 of first wiring layer 303 using chemo-mechanical polishing (CMP).

At 406, the fabrication equipment deposits and/or etches additional layers, including dielectric and wiring layers, as desired according to a fabrication design. An example implementation of a fabrication stack with a single wiring layer in single-crystalline substrate trenches is shown in FIG. 3E.

### A Wiring Layer and an Insulating Layer Imbedded in a Single-Crystalline Substrate Trench

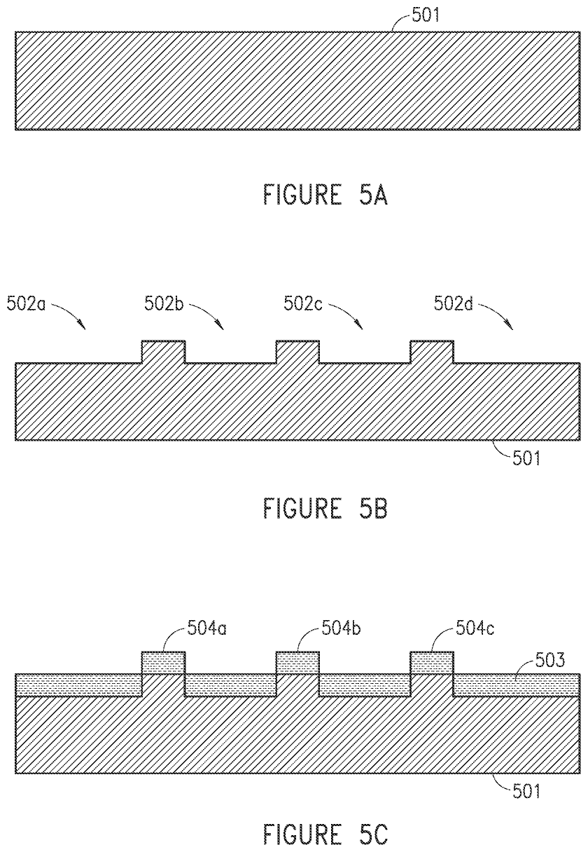

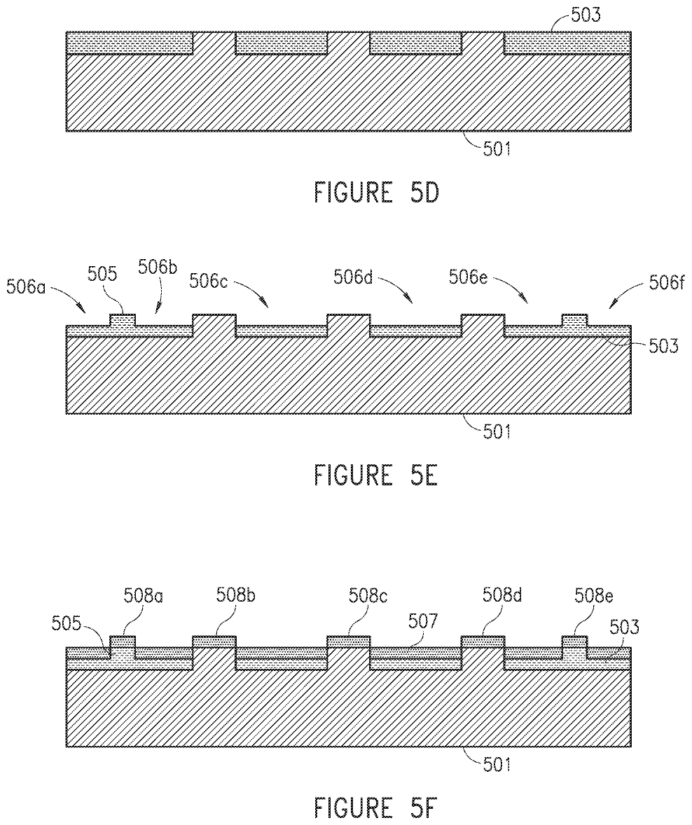

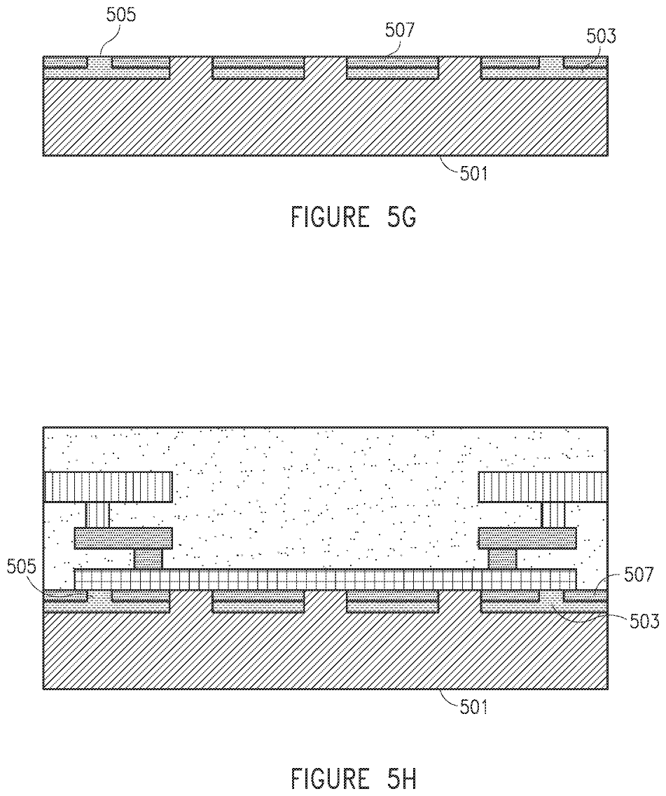

FIGS. 5A through 5H are respective cross-sectional views of a portion of an example superconducting qubit at sequential phases of a fabrication process with a wiring layer and an insulating layer in a single-crystalline substrate trench. The superconducting qubit may be a fluxonium qubit with a kinetic inductor, for example superconducting qubit 200 of FIG. 2. In one example implementation, the single-crystalline substrate is a c-Silicon wafer with high-resistivity, usually 3,000-5,000 Ω·cm.

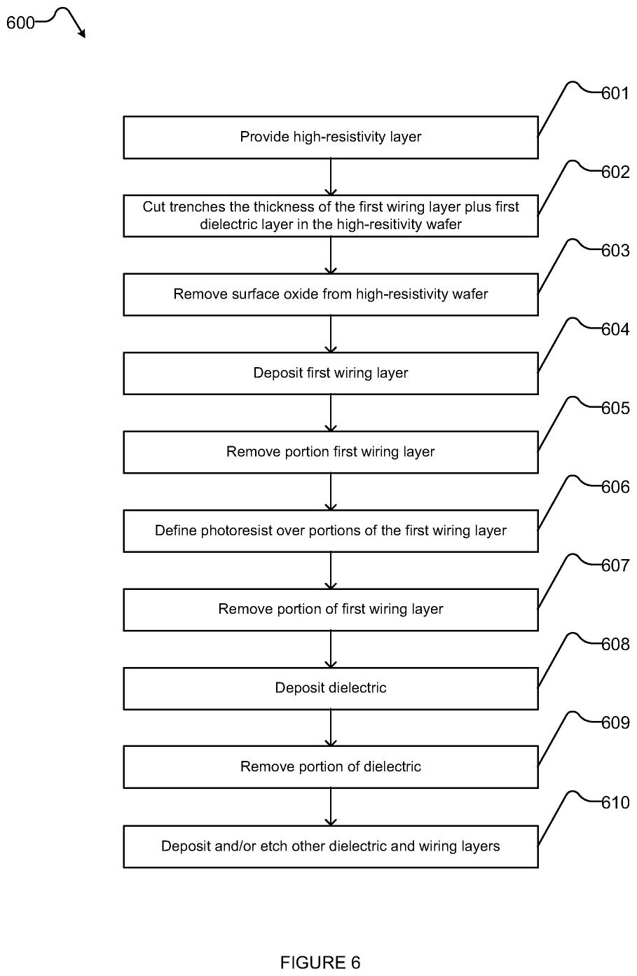

FIG. 6 is a flow diagram of an example fabrication method 600 to produce the structures illustrated in FIGS. 5A through 5H. FIG. 6 will be described with reference to FIGS. 5A though 5H. Method 600 comprises acts 601 to 610; however, a person skilled in the art will understand that the number of acts is exemplary and, in some implementations, certain acts may be omitted, further acts may be added, and/or the order of the acts may be changed. Method 600 may be performed by fabrication equipment.

At 601, the fabrication equipment provides a high-resistivity substrate or layer 501. High-resistivity substrate or layer 501 may be a single-crystalline substrate, for example c-silicon wafer.

At 602, the fabrication equipment cuts (e.g., etches) trenches 502a through 502d (collectively, 502) in high-resistivity wafer 501, as shown in FIG. 5B. In FIGS. 5B though 5H, four trenches are shown; however, a person skilled in the art would understand that the number and the location of the trenches shown is for example purposes only and in different implementations a larger or smaller number of trenches may be cut at 602. The thickness or depth of trenches 502 is equivalent to the thickness or height of a wiring layer plus the thickness or height of a dielectric layer, both to be deposited in trenches 502. In one implementation, a wiring layer may be 300 nm thick or high for Al wires and a dielectric layer 200 nm thick or high, therefore trenches 502 may be 500 nm thick or deep. In another implementation, a wiring layer may be 50 nm thick or high for NbN wires. The location of trenches 502 corresponds to the location where a wiring layer will be defined in the fabrication stack.

At 603, the fabrication equipment removes surface oxide from high-resistivity wafer 501. In some implementations, the fabrication equipment removes surface oxide using a Hydrofluoric acid (HF) dip or an RCA clean.

At 604, the fabrication equipment deposits a first wiring layer 503 to at least partially overlie high-resistivity layer 501, so that first wiring layer 503 is defined in trenches 502 and completely fills trenches 502 and possibly extends upwardly from portions of the high-resistivity layer 501 that surround the trenches 502, overlying the upper surface of high-resistivity layer 501. In some implementations, the fabrication equipment removes any native oxide off trenches 502 before depositing first wiring layer 503. First wiring layer 503 may be a Niobium (Nb), Aluminum (Al) or Tantalum (Ta) layer. In some implementations, first wiring layer 503 may comprise the kinetic inductor of a superconducting qubit, e.g., kinetic inductor 202 of qubit 200.

At 605, the fabrication equipment removes first portions 504a through 504c (collectively, 304) of first wiring layer 503. First portions 504 of first wiring layer 503 extends outwardly with respect to those portions deposited in trenches 502. A person skilled in the art will understand that the number of first portions 504 to be removed varies in different implementation. In some implementations, the fabrication equipment polishes off first portions 504 of first wiring layer 503 using chemo-mechanical polishing (CMP).

At 606, the fabrication equipment defines a photoresist over portions of first wiring layer 503. In one example implementation, a photoresist is defined over first wiring layer 503 over the area where stud vias 505 (only one called out in FIG. 5E for simplicity) will be fabricated.

At 607, the fabrication equipment removes second portions 506a through 506f (FIG. 5D, collectively, 506) of first wiring layer 503. A person skilled in the art will understand that the number of second portions 506 to be removed varies in different implementation. In some implementations, the fabrication equipment etches back second portions 506 of first wiring layer 503 to the desired thickness of first wiring layer 503. In some implementations, the desired thickness or height of first wiring layer 503 is 300 nm for Al Wires. In other implementations, the desired thickness or height of first wiring layer 503 is 50 nm for NbN wires.

At 608, the fabrication equipment deposits a dielectric 507 (FIG. 5F) to overlie at least a portion of first wiring layer 503, so that dielectric 507 is defined in trenches 502 and completely fills trenches 502. In one implementation, dielectric 507 may be Silicon Oxide (SiOx). Other materials that can be used in dielectric 507 may be silicon nitride and hydrogenated amorphous silicon.

At 609, the fabrication equipment removes portions 508a through 508e (collectively, 508) of dielectric 507. Portions 508 of dielectric 507 extend over trenches 502. A person skilled in the art will understand that the number of portions 508 to be removed varies in different implementation. In some implementations, the fabrication equipment polishes off portions 508 of dielectric 507 using chemo-mechanical polishing (CMP). After 609, the thickness or height of first wiring layer 503 plus the thickness or height of dielectric 507 is equivalent to the depth of trenches 502, as best illustrated in FIG. 5G.

At 610, the fabrication equipment deposits and/or etches additional layers, including dielectric and wiring layers, as desired according to a fabrication design. An example implementation of a fabrication stack with a wiring layer and an insulating layer in single-crystalline substrate trenches is shown in FIG. 5H.

### Multiple Wiring Layers Embedded in a Single-Crystalline Substrate Trench

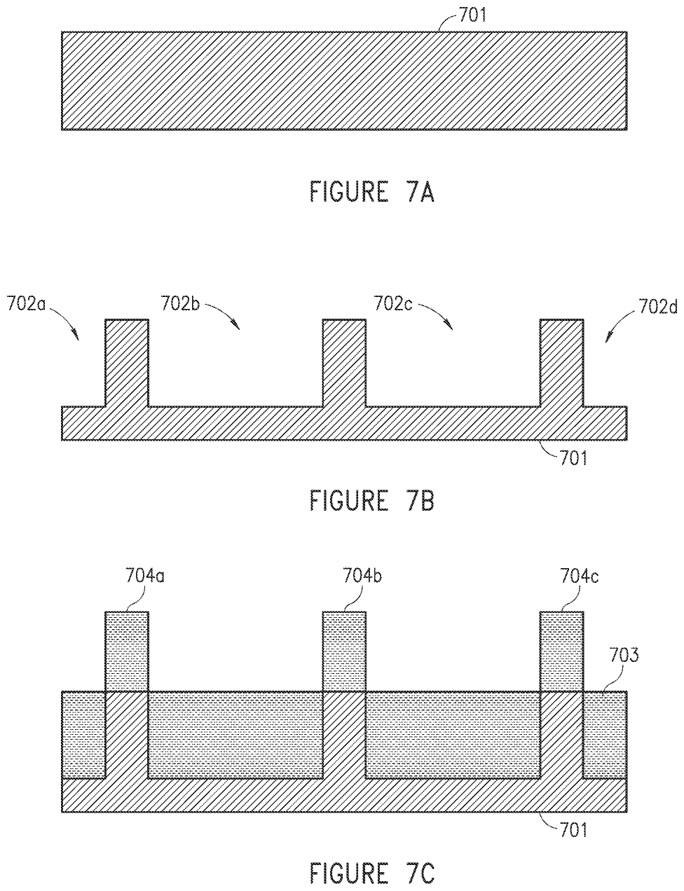

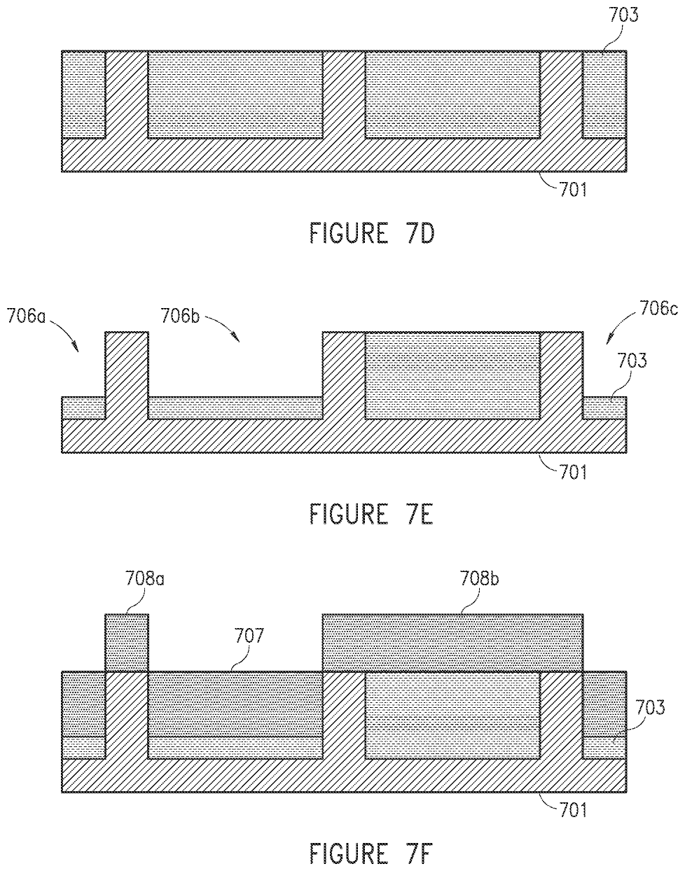

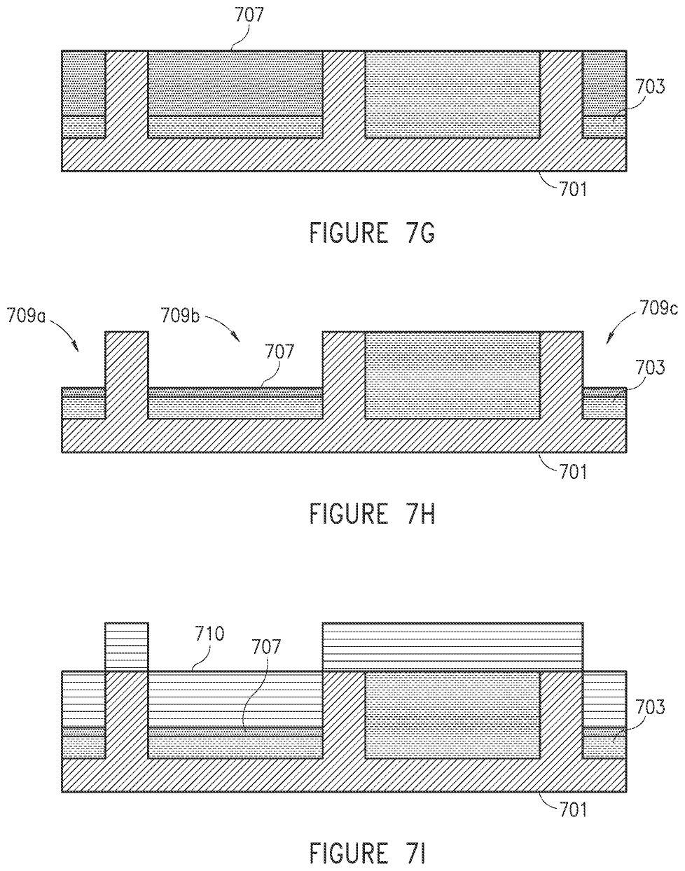

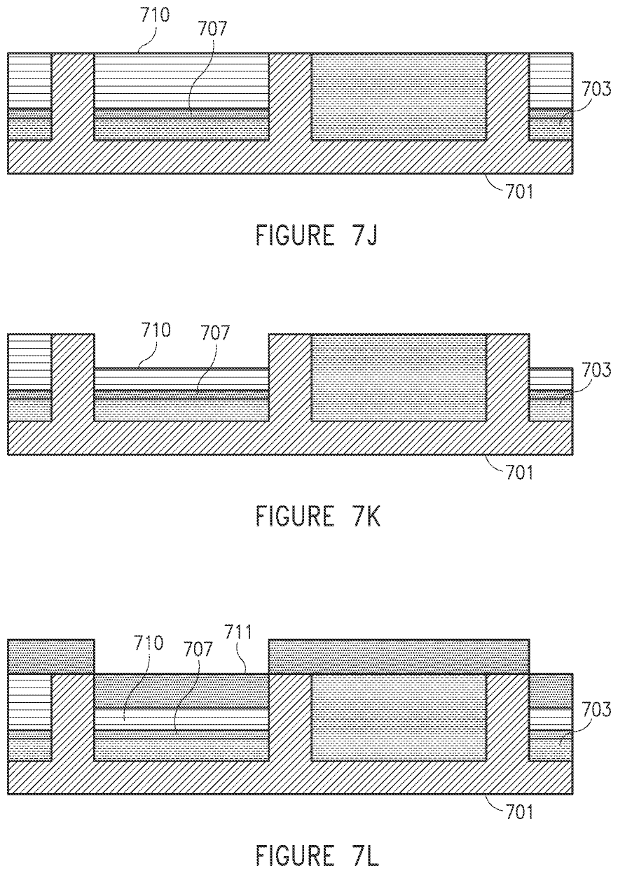

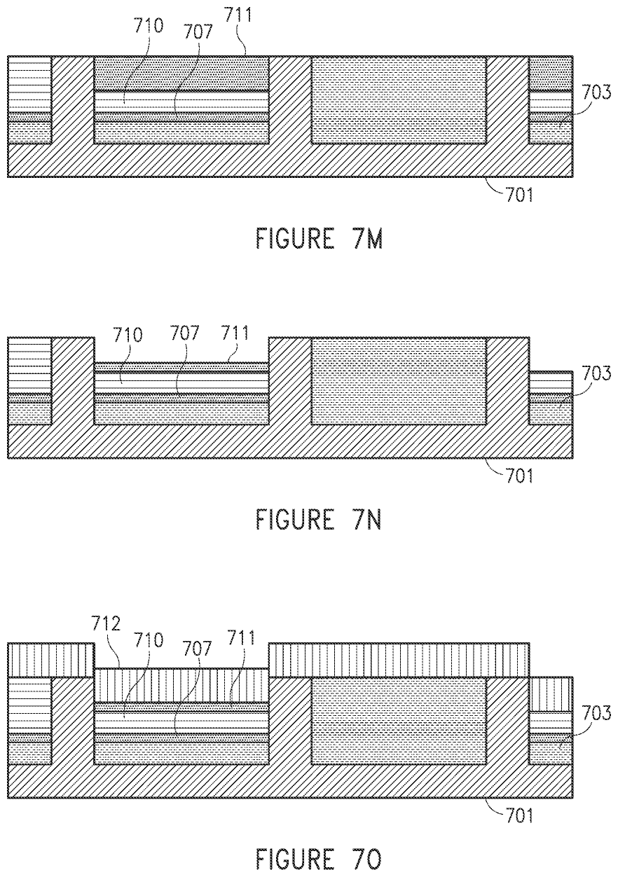

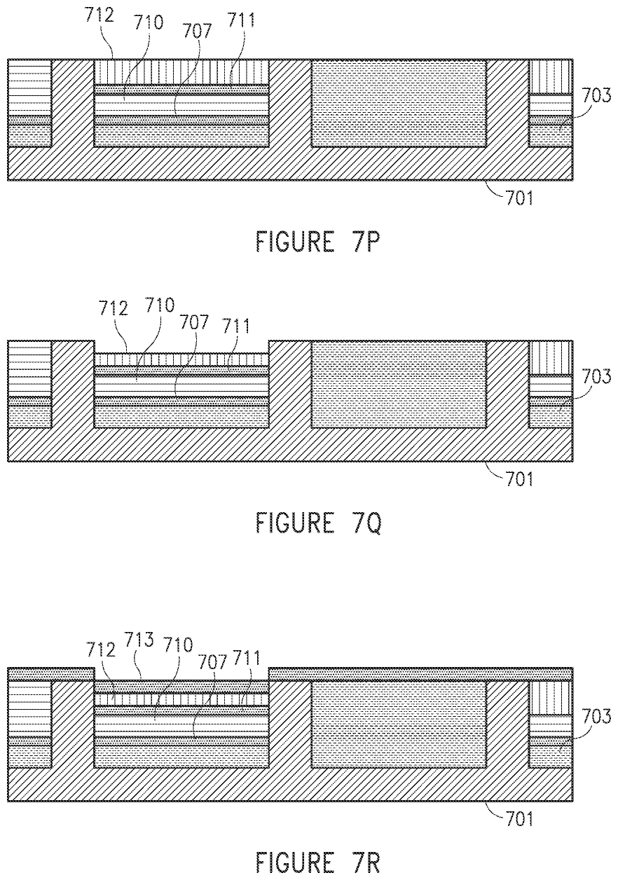

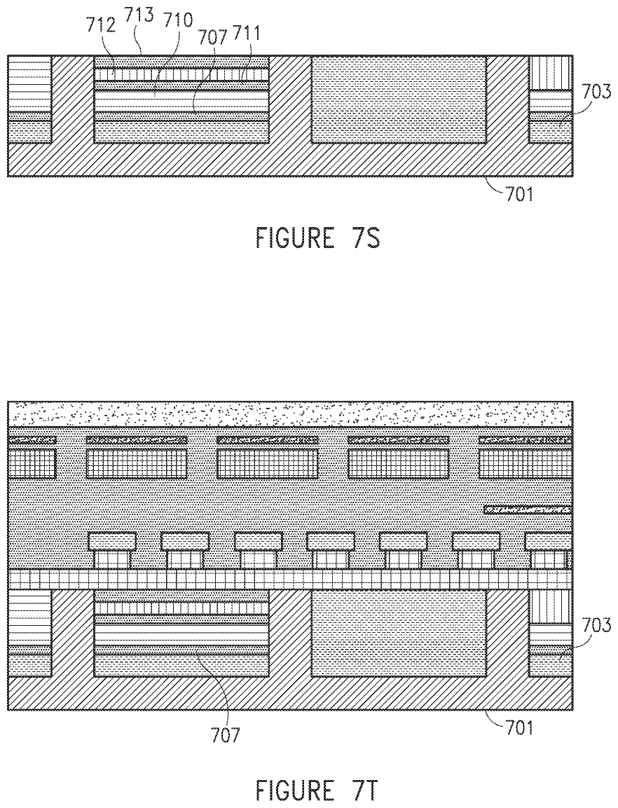

FIGS. 7A through 7T are respective cross-sectional views of a portion of an example superconducting qubit at sequential phases of a fabrication process with multiple wiring layers embedded in a single-crystalline substrate trench. The superconducting qubit may be a fluxonium qubit with a kinetic inductor, for example superconducting qubit 200 of FIG. 2. In one example implementation, the single-crystalline substrate is a c-silicon wafer with high-resistivity, usually 3,000-5,000 Ω·cm.

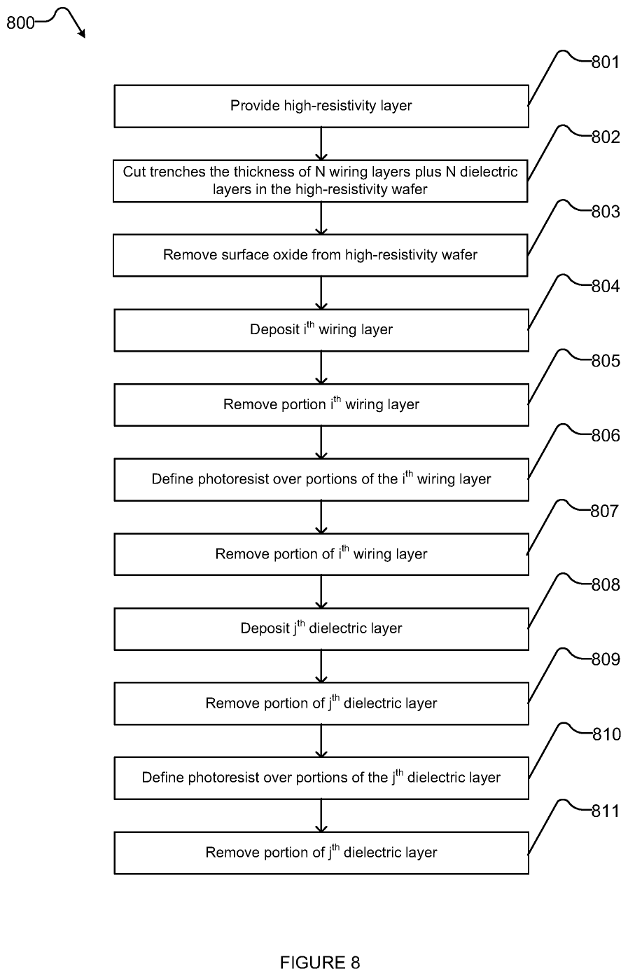

FIG. 8 is a flow diagram of an example fabrication method 800 to produce the structures illustrated in FIGS. 7A through 7T. FIG. 8 will be described with reference to FIGS. 7A though 7T. Method 800 comprises acts 801 to 811; however, a person skilled in the art will understand that the number of acts is exemplary and, in some implementations, certain acts may be omitted, further acts may be added, and/or the order of the acts may be changed. Method 800 may be performed by fabrication equipment.

At 801, the fabrication equipment provides a high-resistivity substrate or layer 701 (FIG. 7A). High-resistivity substrate or layer 701 may be a single-crystalline substrate, for example a c-silicon wafer.

At 802, the fabrication equipment cuts (e.g., etches) trenches 702a through 702d (collectively, 702) in high-resistivity wafer 701, as shown in FIG. 7B. In FIG. 7B through 7T, four trenches are shown; however, a person skilled in the art would understand that the number and the location of the trenches shown is for example purposes only and in different implementations a higher or lower number of trenches may be cut at 802. The depth of trenches 702 is equivalent to the thickness or height of N wiring layers plus the thickness or height of N dielectric layers, to be deposited in trenches 702. In one implementation, a wiring layer may be 300 nm thick or high and a dielectric layer 200 nm thick or high, therefore trenches 802 may be (300·N)+(200·N) nm thick or deep. In other implementations, the wiring layers are 50 nm thick or high for NbN wires. The location of trenches 702 corresponds to the location where N wiring layers will be defined in the fabrication stack.

At 803, the fabrication equipment removes surface oxide from high-resistivity wafer 701. In some implementations, the fabrication equipment removes surface oxide using a Hydrofluoric acid (HF) dip or an RCA clean.

Acts 804 through 811 repeats until the desired number of N wiring layers and N dielectric layers have been deposited.

At 804, the fabrication equipment deposits an i^{th} wiring layer 703, where 1≤i≤N, to at least partially overlie high-resistivity layer 701, so that i^{th} wiring layer 703 is defined in trenches 702 and completely fills trenches 702, for example as shown in FIG. 7C. The i^{th} wiring layer 703 may be a Niobium (Nb), Aluminum (Al) or Tantalum (Ta) layer. In some implementations, i^{th} wiring layer may comprise the kinetic inductor of a superconducting qubit, e.g., kinetic inductor 202 of qubit 200.

At 805, the fabrication equipment removes first portions 704a through 704c (collectively, 704) of i^{th} wiring layer 703. First portions 704 of i^{th} wiring layer 703 extends over trenches 702 as illustrated in FIGS. 7C and 7D. A person skilled in the art will understand that the number of first portions 704 to be removed varies in different implementation. In some implementations, the fabrication equipment polishes off first portions 704 of i^{th} wiring layer 703 using chemo-mechanical polishing (CMP), for example as illustrated in FIG. 7D.

At 806, the fabrication equipment defines a photoresist over portions of i^{th} wiring layer 703.

At 807, the fabrication equipment removes second portions 706a through 706c (visible in FIG. 7E, collectively, 706) of i^{th} wiring layer 703. A person skilled in the art will understand that the number of second portions 706 to be removed varies in different implementation. In some implementations, the fabrication equipment etches back second portions 706 of i^{th} wiring layer 703 to the desired thickness or height of i^{th} wiring layer 703 as best seen in FIG. 7E. In some implementations, the desired thickness or height of i^{th} wiring layer 703 is 300 nm for Al wires. In other implementations, the desired thickness or height of i^{th} wiring layer 703 is 50 nm for NbN wires.

At 808, the fabrication equipment deposits a j^{th} dielectric layer 707 (FIG. 7F), where 1≤j≤N, to overlie at least a portion of i^{th} wiring layer 703, so that j^{th} dielectric layer 707 is defined in trenches 702 and completely fills trenches 702. In one implementation, j^{th} dielectric layer 707 may be Silicon Oxide (SiOx). Other materials that can be used in j^{th} dielectric layer 707 may be silicon nitride and hydrogenated amorphous silicon.

At 809, the fabrication equipment removes first portions 708a trough 708b (visible in FIG. 7F, collectively, 708) of j^{th} dielectric layer 707. First portions 708a of j^{th} dielectric layer 707 extends over trenches 702. A person skilled in the art will understand that the number of first portions 708 to be removed varies in different implementation. In some implementations, the fabrication equipment polishes off first portions 708 of j^{th} dielectric layer 707 using chemo-mechanical polishing (CMP), for example as illustrated in FIG. 7G. After 809, the thickness or height of i wiring layers plus the thickness or height of j dielectric layers is equivalent to the depth of trenches 702.

At 810, the fabrication equipment defines a photoresist over portions of j^{th} dielectric layer 707.

At 811, the fabrication equipment removes second portions 709a through 709c (visible in FIG. 7H, collectively, 709) of j^{th} dielectric layer 707. A person skilled in the art will understand that the number of second portions 709 to be removed varies in different implementation. In some implementations, the fabrication equipment etches back second portions 709 of j^{th} dielectric layer 707 to the desired thickness or height of j^{th} dielectric layer 707. In some implementations, the desired thickness or height of j^{th} dielectric layer 707 is 200 nm.

As mentioned above, acts 804 through 811 repeats until N wiring layers and N dielectric layers have been deposited, as shown in the example implementation of FIGS. 7C through 7S, where additional wiring layers 710 and 712 are deposited and additional dielectric layers 711 and 713 are deposited. When N wiring layers and N dielectric layers have been deposited, the fabrication equipment may deposit and/or etch additional wiring layers, as desired according to a fabrication design. An example implementation of a fabrication stack with multiple wiring layers in single-crystalline substrate trenches is shown in FIG. 7T.

While method 600 and 800 deposit dielectric between wiring layers, the lower-quality (e.g., noisy) dielectrics have limited volume compared to traditional fabrication stacks without trenches. Additionally, the single-crystalline substrate walls, created by the trenches, are between two sides of a qubit wire, thus higher-quality (e.g., high-resistivity) dielectric is located in a region of both high electric and high magnetic fields to provide reduced exposure to flux noise sources found in many deposited dielectrics.

The above described method(s), process(es), or technique(s) could be implemented by a series of processor readable instructions stored on one or more nontransitory processor-readable media. The above described method(s), process(es), or technique(s) may include various acts, though those of skill in the art will appreciate that in alternative examples certain acts may be omitted and/or additional acts may be added. Those of skill in the art will appreciate that the illustrated order of the acts is shown for example purposes only and may change in alternative examples. Some of the example acts or operations of the above described method(s), process(es), or technique(s) are performed iteratively. Some acts of the above described method(s), process(es), or technique(s) can be performed during each iteration, after a plurality of iterations, or at the end of all the iterations.

The above description of illustrated implementations, including what is described in the Abstract, is not intended to be exhaustive or to limit the implementations to the precise forms disclosed. Although specific implementations of and examples are described herein for illustrative purposes, various equivalent modifications can be made without departing from the spirit and scope of the disclosure, as will be recognized by those skilled in the relevant art. The teachings provided herein of the various implementations can be applied to other methods of quantum computation, not necessarily the exemplary methods for quantum computation generally described above.

The various implementations described above can be combined to provide further implementations. All of the commonly assigned US patent application publications, US patent applications, foreign patents, and foreign patent applications referred to in this specification and/or listed in the Application Data Sheet are incorporated herein by reference, in their entirety, including but not limited to: U.S. Pat. No. 7,533,068 and U.S. Patent Application No. 63/223,686.

These and other changes can be made to the implementations in light of the above-detailed description. In general, in the following claims, the terms used should not be construed to limit the claims to the specific implementations disclosed in the specification and the claims, but should be construed to include all possible implementations along with the full scope of equivalents to which such claims are entitled. Accordingly, the claims are not limited by the disclosure.

1. A superconducting device comprising:
a body loop comprising:
a Josephson junction structure comprising at least one inductor in series with at least one Josephson junction; and
a kinetic inductor, the kinetic inductor comprising a segment of kinetic inductance material.

2. The superconducting device of claim 1, wherein the body loop has a body loop material comprising at least one of Al and Nb.

3. The superconducting device of claim 1 wherein the Josephson junction structure comprises a compound Josephson junction, each Josephson junction in the compound Josephson junction in series with a respective inductor.

4. The superconducting device of claim 1, wherein the segment of kinetic inductance material comprises at least one of NbN, NbTiN, TiN, AlN and granular Aluminum.

5. The superconducting device of claim 1, wherein the kinetic inductor is embedded into a first layer and the Josephson junction structure is embedded into a second layer, the second layer separate from the first layer.

6. The superconducting device of claim 5, wherein the first layer is adjacent to a high-resistivity layer.

7. The superconducting device of claim 5, wherein the first layer is interposed within a high-resistivity layer.

8. The superconducting device of claim 6 or 7, wherein the high-resistivity layer is a single-crystalline substrate layer.

9. The superconducting device of claim 8, wherein the single-crystalline substrate layer is selected from a group comprising: c-Silicon and Sapphire.

10. The superconducting device of claim 7, further comprising an insulating layer interposed within the high-resistivity layer.

11. The superconducting device of claim 10, further comprising a plurality of wiring layers interposed within the high-resistivity layer.

12. The superconducting device of claim 5, wherein the first and the second layer are separated by at least one insulating dielectric layer.

13. The superconducting device of claim 5, wherein the first and the second layer are separated by N dielectric-wiring layer pairs.

14. The superconducting device of claim 13, wherein at least one of the N dielectric-wiring layer pairs comprises a Al.

15. A processor comprising a plurality of superconducting devices, each superconducting device comprising:
a body loop comprising:
a Josephson junction structure comprising at least one inductor in series with at least one Josephson junction; and
a kinetic inductor, the kinetic inductor comprising a segment of kinetic inductance material.

16. The processor of claim 15, wherein the body loop has a body loop material comprising at least one of Al and Nb.

17. The processor of claim 15, wherein the Josephson junction structure comprises a compound Josephson junction, each Josephson junction in the compound Josephson junction in series with a respective inductor.

18. The processor of claim 15, wherein the segment of kinetic inductance material comprises at least one of NbN, NbTiN, TiN, AlN, and granular Aluminum.

19. The processor of claim 15, wherein the kinetic inductor is embedded into a first layer and the Josephson junction structure is embedded into a second layer, the second layer separate from the first layer.

20. The processor of claim 19, wherein the first layer is adjacent to a high-resistivity layer.

21. The processor of claim 19, wherein the first layer is interposed within the high-resistivity layer.

22. The processor of claim 20 or 21, wherein the high-resistivity layer is a single-crystalline substrate layer.

23. The processor of claim 22, wherein the single-crystalline substrate layer is selected from a group comprising: c-Silicon and Sapphire.

24. The processor of claim 21, further comprising an insulating layer interposed within the high-resistivity layer.

25. The processor of claim 24, further comprising a plurality of wiring layers interposed within the high-resistivity layer.

26. The processor of claim 19, wherein the first and the second layer are separated by at least one insulating dielectric layer.

27. The processor of claim 19, wherein the first and the second layer are separated by N dielectric-wiring layer pairs.

28. The processor of claim 27, wherein at least one of the N dielectric-wire layer pairs comprises Al.

29. The processor of claim 15, wherein each superconducting device in the plurality of superconducting devices is a qubit.

30. The processor of claim 29, wherein the plurality of qubits is operable to perform gate-model quantum computation.

31. A method of fabrication of a superconducting device, the method comprising:
providing a high-resistivity layer;
defining trenches in the high-resistivity layer;
depositing a first superconducting wiring layer to overlie at least a portion of the high-resistivity layer and within the trenches, wherein the first superconducting wiring layer comprises material that is superconducting in a range of critical temperatures; and
removing a portion of the first superconducting wiring layer from the high-resistivity layer to define the first superconducting wiring layer within the trenches.

32. The method of claim 31, wherein depositing a high-resistivity layer includes depositing a single-crystalline substrate layer.

33. The method of claim 31, wherein depositing a single-crystalline substrate layer includes depositing a single-crystalline substrate selected from a group comprising: c_Silicon and Sapphire.

34. The method of claim 31, further comprising removing oxide from the high-resistivity layer before depositing a first superconducting wiring layer.

35. The method of claim 34, wherein removing oxide from the high-resistivity layer includes removing oxide from the high-resistivity layer using a Hydrofluoric acid (HF) dip.

36. The method of claim 31, wherein defining trenches in the high-resistivity layer includes forming trenches in the high-resistivity layer having a depth that matches a depth of the first superconducting wiring layer in all places where the first superconducting wiring layer will be defined.

37. The method of claim 31, wherein depositing a first superconducting wiring layer includes deposing a material selected from a group comprising Nb, Al, and Ta.

38. The method of claim 31, wherein depositing a first superconducting wiring layer includes deposing a segment of kinetic inductor material.

39. The method of claim 38, wherein deposing a segment of kinetic inductor material includes depositing a segment of material selected from a group comprising NbN, NbTiN, TiN, AlN, and granular Aluminum.

40. The method of claim 31, wherein removing a portion of the first superconducting wiring layer from the high-resistivity layer includes polishing off a portion of the first superconducting wiring layer using chemo-mechanical polishing (CMP).

41. A method of fabrication of a superconducting device, the method comprising:
providing a high-resistivity layer;
defining trenches in the high-resistivity layer;
depositing a first superconducting wiring layer to overlie at least a portion of the high-resistivity layer and within the trenches, wherein the first superconducting wiring layer comprises material that is superconducting in a range of critical temperatures;
removing a first portion of the first superconducting wiring layer from the high-resistivity layer to define the first superconducting wiring layer within the trenches;
defining a photoresist over a first region of the first superconducting wiring layer within the trenches;
removing a second portion of the first superconducting wiring layer to define studs for vias;
depositing a dielectric layer to overlie the first superconducting wiring layer; and
removing a first portion of the dielectric layer to define the dielectric layer within the trenches.

42. The method of claim 41, wherein providing a high-resistivity layer includes providing a single-crystalline substrate layer.

43. The method of claim 42, wherein providing a single-crystalline substrate layer includes providing a single-crystalline substrate selected from a group comprising: c-Silicon and Sapphire.

44. The method of claim 41, further comprising removing oxide from the high-resistivity layer before depositing a first superconducting wiring layer.

45. The method of claim 44, wherein removing oxide from the high-resistivity layer includes removing oxide from the high-resistivity layer using a Hydrofluoric acid (HF) dip.

46. The method of claim 41, wherein defining trenches in the high-resistivity layer includes forming trenches having a depth that at least approximately matches a height of the first superconducting wiring layer plus a height of the dielectric layer in the high-resistivity layer in all places where the first superconducting wiring layer will be defined.

47. The method of claim 41, wherein depositing a first superconducting wiring layer to overlie at least a portion of the high-resistivity layer and within the trenches includes depositing a first superconducting wiring layer to overlie at least a portion of the high-resistivity layer to fill the trenches.

48. The method of claim 41, wherein depositing a first superconducting wiring layer includes deposing a material selected from a group comprising Nb, Al, and Ta.

49. The method of claim 41, wherein depositing a first superconducting wiring layer includes deposing a segment of kinetic inductor material.

50. The method of claim 49, wherein deposing a segment of kinetic inductor material includes depositing a segment of material selected from a group comprising NbN, NbTiN, TiN, AlN, and granular Aluminum.

51. The method of claim 41, wherein removing a first portion of the first superconducting wiring layer includes polishing off a first portion of the first superconducting wiring layer using chemo-mechanical polishing (CMP).

52. The method of claim 41, wherein defining a photoresist over a first region of the first superconducting wiring layer within the trenches includes defining a photoresist over a first region of the first superconducting wiring layer within the trenches, the first region comprising studs for vias.

53. The method of claim 41, wherein removing a second portion of the first superconducting wiring layer includes etching a second portion of the first superconducting wiring layer.

54. The method of claim 41, wherein depositing a dielectric layer to overlie the first superconducting wiring layer includes depositing a dielectric layer to overlie the first superconducting wiring layer to fill the trenches.

55. The method of claim 41, wherein removing a first portion of the dielectric layer includes polishing off a first portion of the dielectric layer using CMP.

56. A method of fabrication of a superconducting device, the method comprising:
providing a high-resistivity layer;
defining trenches in the high-resistivity layer;
until i=N and j=N, where N>1, repeating:
depositing an i^{th} superconducting wiring layer to overlie at least a portion of the high-resistivity layer and within the trenches, wherein the i^{th} superconducting wiring layer comprises material that is superconducting in a range of critical temperatures;
removing a respective first portion of the i^{th} superconducting wiring layer from the high-resistivity layer to define the i^{th} superconducting wiring layer within the trenches;
defining a photoresist over a respective first region of the i^{th} superconducting wiring layer within the trenches;
removing a respective second portion of the i^{th} superconducting wiring layer to define studs for vias;
depositing a j^{th} dielectric layer to overlie the i^{th} superconducting wiring layer;
removing a respective first portion of the j^{th} dielectric layer to define the j^{th} dielectric layer in the trenches;
defining a photoresist over a respective first region of the j^{th} dielectric layer within the trenches; and
removing a respective second portion of the j^{th} dielectric layer.

57. The method of claim 56, wherein providing a high-resistivity layer includes providing a single-crystalline substrate layer.

58. The method of claim 57, wherein providing a single-crystalline substrate includes providing a single-crystalline substrate selected from a group comprising: c-Silicon and Sapphire.

59. The method of claim 56, wherein removing oxide from the high-resistivity layer includes removing oxide from the high-resistivity layer using an Hydrofluoric acid (HF) dip.

60. The method of claim 56, wherein defining trenches in the high-resistivity layer includes forming trenches having a depth equal to a height of N superconducting wiring layers plus a height of N dielectric layers in the high-resistivity layer in all places where the N superconducting wiring layers will be defined.

61. The method of claim 56, wherein depositing an i^{th} superconducting wiring layer includes deposing a material selected from a group comprising Nb, Al, and Ta.

62. The method of claim 56, wherein depositing an i^{th} superconducting wiring layer includes deposing a segment of kinetic inductor material.

63. The method of claim 62, wherein deposing a segment of kinetic inductor material includes depositing a segment of material selected from a group comprising NbN, NbTiN, TiN, AlN, and granular Aluminum.

64. The method of claim 56, wherein depositing an i^{th} superconducting wiring layer includes depositing the i^{th} superconducting wiring layer to completely fill the trenches.

65. The method of claim 56, wherein removing a respective first portion of the i^{th} superconducting wiring layer includes polishing off a respective first portion of the i^{th} superconducting wiring layer using CMP.

66. The method of claim 56, wherein defining a photoresist over a respective first region of the i^{th} superconducting wiring layer within the trenches includes defining a photoresist over a respective first region of the i^{th} superconducting wiring layer within the trenches, the first region comprising studs for vias.

67. The method of claim 56, wherein removing a respective second portion of the i^{th} superconducting wiring layer includes etching a respective second portion of the i^{th} superconducting wiring layer.

68. The method of claim 56, wherein depositing a j^{th} dielectric layer to overlie the i^{th} superconducting wiring layer includes depositing a j^{th} dielectric layer to overlie the i^{th} superconducting wiring layer to completely fill the trenches.

69. The method of claim 56, wherein removing a respective first portion of the j^{th} dielectric layer includes removing a respective first portion of the j^{th} dielectric layer using CMP.

70. The method of claim 56, wherein defining a photoresist over a respective first region of the j^{th} dielectric layer within the trenches includes defining a photoresist over a respective first region of the j^{th} dielectric layer within the trenches, the first region comprising studs for vias.

71. The method of claim 56, wherein removing a respective second portion of the j^{th} dielectric layer includes etching a respective second portion of the j^{th} dielectric layer.

72. The method of claim 56, further comprising removing oxide from the high-resistivity layer before defining trenches in the high-resistivity layer.
